(19) United States
(12) Patent Application Publication
(10) Pub. No.: US 2016/0181568 A1
(43) Pub. Date: Jun. 23, 2016

(54) DISPLAY DEVICE AND METHOD OF MANUFACTURING THE SAME

(71) Applicant: SAMSUNG DISPLAY CO., LTD., Yongin-City (KR)

(72) Inventors: Sunyoung JUNG, Yongin-City (KR); Ilsang LEE, Yongin-City (KR)

(21) Appl. No.: 14/789,045

(22) Filed: Jul. 1, 2015

(30) Foreign Application Priority Data
Dec. 19, 2014 (KR) 10-2014-0184953

(51) Int. Cl. H01L 51/52; H01L 27/32; H01L 51/56

(52) U.S. Cl. CPC H01L 51/5246; H01L 51/56; H01L 27/3244; H01L 2251/303; H01L 2251/566

(57) ABSTRACT

A display apparatus includes a substrate, an encapsulation substrate that faces the substrate, a display unit on the substrate, the display unit including a display device to display an image, and a sealing unit bonding the substrate and the encapsulation substrate to each other, the sealing unit being separated from the display unit and including silicon oxide and glass frit.

### CROSS-REFERENCE TO RELATED APPLICATION

Korean Patent Application No. 10-2014-0184953, filed on Dec. 19, 2014, in the Korean Intellectual Property Office, and entitled: “Display Device And Method Of Manufacturing The Same”

### BACKGROUND

1. Field

One or more exemplary embodiments relate to a display apparatus and method of manufacturing the same

2. Description of the Related Art

Recently, display apparatuses have been used for various purposes. In particular, as the display apparatuses have been manufactured to be thin and light, a use range thereof has increased.

Diverse methods are used to manufacture such display apparatuses. For example, a display configured to display images is provided between a substrate and an encapsulation substrate, and the substrate and encapsulation substrate are bonded to each other by a sealing unit. The sealing unit stably bonds the substrate and encapsulation substrate to each other and also prevents oxygen, moisture, and impurities from penetrating the display.

### SUMMARY

One or more exemplary embodiments include a display apparatus having improved sealing characteristics and reduced dead space and a method of manufacturing the display apparatus.

According to one or more exemplary embodiments, A display apparatus includes a substrate, an encapsulation substrate that faces the substrate, a display unit on the substrate, the display unit including a display device to display an image, and a sealing unit bonding the substrate and the encapsulation substrate to each other, the sealing unit being separated from the display unit and including silicon oxide and glass frit.

A portion of the sealing unit adjacent to the display may include silicon.

The silicon oxide may be formed of silicon crystallized at a temperature ranging from about 250 to about 300° C.

A glass transition temperature (Tg) of the glass frit may be lower than or equal to 200° C.

The glass frit may contain at least vanadium oxide or bismuth oxide.

The vanadium oxide may contain V₂O₅ and the bismuth oxide may contain Bi₂O₃.

The glass frit may contain at least one selected from the group consisting of TeO₂, ZnO, and BaO.

The display apparatus may further include a wiring unit connected to the display unit and including a plurality of wires extending toward an edge of the substrate.

The sealing unit may surround the display unit and may overlap at least the wiring unit.

A gap between the substrate and encapsulation substrate may be sealed by the sealing unit.

The display unit may include an organic light-emitting display device, and the organic light-emitting display device may include a first electrode, a second electrode, and an intermediate layer disposed between the first electrode and the second electrode and including an emission layer.

The display apparatus may further include a thin-film transistor (TFT) electrically connected to the first electrode and including an active layer, a gate electrode, a source electrode, and a drain electrode.

According to one or more exemplary embodiments, a method of manufacturing a display apparatus, includes: preparing a substrate and an encapsulation substrate that faces the substrate; forming a display unit between the substrate and the encapsulation substrate and configured to display an image; and bonding the substrate and the encapsulation substrate via a sealing unit formed by sintering a binder and a glass frit to which the binder is added.

The bonding may include: forming a preliminary sealing unit including a paste including the glass frit and the binder on a surface of the substrate or the encapsulation substrate and then sintering and drying the preliminary sealing unit; and melting and hardening the preliminary sealing unit by emitting a laser beam after the preliminary sealing unit is sintered and dried and the substrate and the encapsulation substrate are arranged so that the preliminary sealing unit becomes the sealing unit.

The paste may be formed by preparing a powder containing the glass frit and adding the binder and a solution to the powder.

The forming of the preliminary sealing unit may include forming the paste as desired by using a screen printing method.

The preparing may include: preparing a mother substrate greater than the substrate and a mother encapsulation substrate greater than the encapsulation substrate; and performing a cutting process on the mother substrate and the encapsulation substrate after the sealing unit is formed.

The display may include a plurality of display units, and the cutting process may be performed to separate the plurality of display units from each other.

The sealing unit may surround each of the plurality of display units.

A temperature of the laser beam may be lower than or equal to 400° C.

### BRIEF DESCRIPTION OF THE DRAWINGS

Features will become apparent to those of ordinary skill in the art by describing in detail exemplary embodiments with reference to the attached drawings, in which:

FIG. 1 illustrates a schematic cross-sectional view of an edge of a display apparatus according to an exemplary embodiment;

FIG. 2 illustrates an enlarged view of a sealing unit of FIG. 1;

FIG. 3 illustrates a schematic cross-sectional view of an edge of a display apparatus according to another exemplary embodiment;

FIG. 4 illustrates an enlarged view of an area X of FIGS. 2 and 3;

FIG. 5 illustrates a schematic cross-sectional view of a modified exemplary embodiment of FIG. 4;

FIG. 6 illustrates a schematic cross-sectional view of another modified exemplary embodiment of FIG. 4;

FIG. 7 illustrates a schematic cross-sectional view of another modified exemplary embodiment of FIG. 4; and

FIGS. 8A to 8F illustrate diagrams of stages in a method of manufacturing a display apparatus, according to an exemplary embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” or “above” another layer or substrate, it can be directly on or above the other layer or substrate, or intervening layers or elements may also be present. In addition, it will also be understood that when a layer or element is referred to as being “between” two layers or elements, it can be the only layer or element between the two layers or elements, or one or more intervening layers or elements may also be present. Like reference numerals refer to like elements throughout.

While such terms as “first”, “second”, etc., may be used to describe various components, such components are not limited to the above terms. The above terms are used only to distinguish one component from another.

A conventional display apparatus may include a substrate, a display unit, an encapsulation substrate, and a sealing unit. Also, the conventional display apparatus may further include a wiring unit adjacent to the display unit. The sealing unit of the conventional display apparatus may be formed of glass which may completely block penetration of moisture or air into the display unit, e.g., the sealing unit may include glass frit.

When the sealing unit of the conventional display apparatus is formed of glass, it is separated from the display unit and the wiring unit by a certain distance. In detail, since the sealing unit of the conventional display apparatus is formed of glass, the sealing unit may be heated at a high temperature during a melting process. Therefore, if the sealing unit were to be placed in contact with the display unit and the wiring unit, or when the sealing unit were to be arranged adjacent thereto, a wire of the wiring unit or an emission area of the display unit could be damaged by heat of the sealing unit (during hardening thereof). Thus, the sealing unit of the conventional display apparatus is separated from the display unit and the wiring unit to prevent the damage.

However, when the sealing unit of the conventional display apparatus is separated from the display unit and the wiring unit, a dead space in a mother substrate and a material loss may be increased. Thus, visibility of the display devices is decreased.

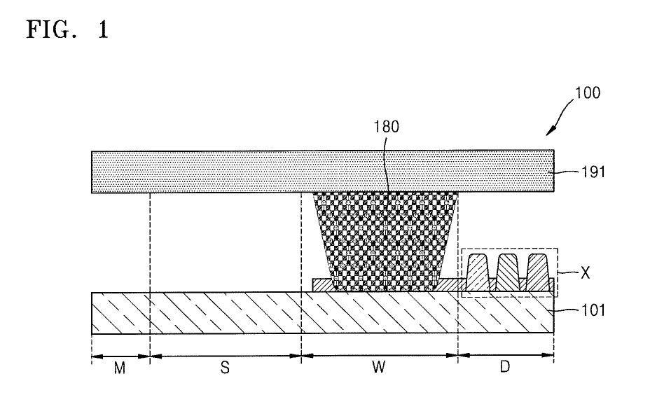

Therefore, according to one or more embodiments, a sealing unit is moved inward, i.e., toward the wiring unit, to reduce a dead space, such that the sealing unit is placed in contact with the wiring unit. Also, the sealing unit for sealing the substrate and the encapsulation substrate at a low temperature is provided to prevent damage caused by the movement of the sealing unit. This will be described in detail below with reference to FIG. 1

FIG. 1 illustrates a schematic cross-sectional view of an edge of a display apparatus 100 according to an exemplary embodiment.

Referring to FIG. 1, the display apparatus 100 may include a substrate 101, a display unit D, an encapsulation substrate 191, and a sealing unit 180. Also, the display apparatus 100 may further include a wiring unit W adjacent to the display unit D. As shown in FIG. 1, in the display apparatus 100, the sealing unit 180 is moved inward, i.e., from region S toward the wiring unit W (along the arrow), to directly contact the wiring unit W.

The substrate 101 may include, e.g., a transparent glass which mainly contains silicon oxide (SiO₂). In addition, the substrate 101 may also include transparent plastics. However, as a laser beam is irradiated when the sealing unit 180 is formed, glass may be used to form the substrate 101, e.g., due to better heat resistance as compared to plastics.

The display unit D is formed on the substrate 101. The display unit D may be, e.g., an organic light-emitting display device, a liquid crystal display device, or the like, and provides images to a user. Detailed descriptions of the display unit D will be provided with reference to FIGS. 5 to 8.

The encapsulation substrate 191 faces the substrate 101. The display unit D is arranged between the substrate 101 and the encapsulation substrate 191. The encapsulation substrate 191 may include, e.g., transparent glass which mainly contains SiO₂. Also, the encapsulation substrate 191 may include transparent plastics. Since a laser beam is irradiated toward the encapsulation substrate 191 when the sealing unit 180 is formed, glass may be used to form the encapsulation substrate 191, e.g., due to better heat resistance as compared to plastics.

The sealing unit 180 is arranged on an edge of the display unit D between the substrate 101 and the encapsulation substrate 191 in order to be separated from the display unit D. The sealing unit 180 may surround the display unit D. In this case, the sealing unit 180 may overlap at least the wiring unit W. As the sealing unit 180 is arranged inward from edges of the substrate 101 and the encapsulation substrate 190 toward the display unit D, a dead space M is reduced. That is, as the sealing unit 180 is arranged on, e.g., directly on, the wiring unit W, i.e., at a further distance from an outermost edge of the substrate 101, the dead space M is reduced. The wiring unit W is connected to the display unit D and may include a plurality of wires extending toward an edge of the substrate 101.

The sealing unit 180 is arranged between the substrate 101 and the encapsulation substrate 190 to bond the same. Also, a space between the substrate 101 and the encapsulation substrate 190 is sealed by the sealing unit 180. Thus, moisture, air, impurities. etc. do not penetrate into the display unit D arranged between the substrate 101 and the encapsulation substrate 190. As a result, the display unit D is not damaged.

The sealing unit 180 is formed by patterning glass frit paste on a surface of the substrate 101 or the encapsulation substrate 191, sintering and drying the glass frit paste, and irradiating a laser beam on the sintered and dried glass frit paste to melt the same. In this case, the glass frit paste is formed by adding a binder and a solution to a powder including a glass frit.

When a temperature of the glass frit paste is equal to or greater than about 600° C. (during formation of the sealing unit 180), a temperature of heat applied to the wiring unit W is about 350° C. at most. Due to the temperature of 350° C., a planarization layer formed of polyimide (PI) on the wiring unit W may be deformed.

Therefore, a temperature of a laser beam irradiated on the sealing unit 180 may be adjusted, e.g., decreased to about 400° C., so the temperature of the wiring unit W is also decreased, i.e., to below 350° C. As such, the planarization layer formed on the wiring unit W may not be damaged.

As shown in FIG. 1, the sealing unit 180 may be arranged to overlap the wiring unit W so that the dead space M may be reduced. Further, the glass frit paste is used to prevent damage of the planarization layer and to form the sealing unit 180 at a temperature lower than or equal to 400° C.

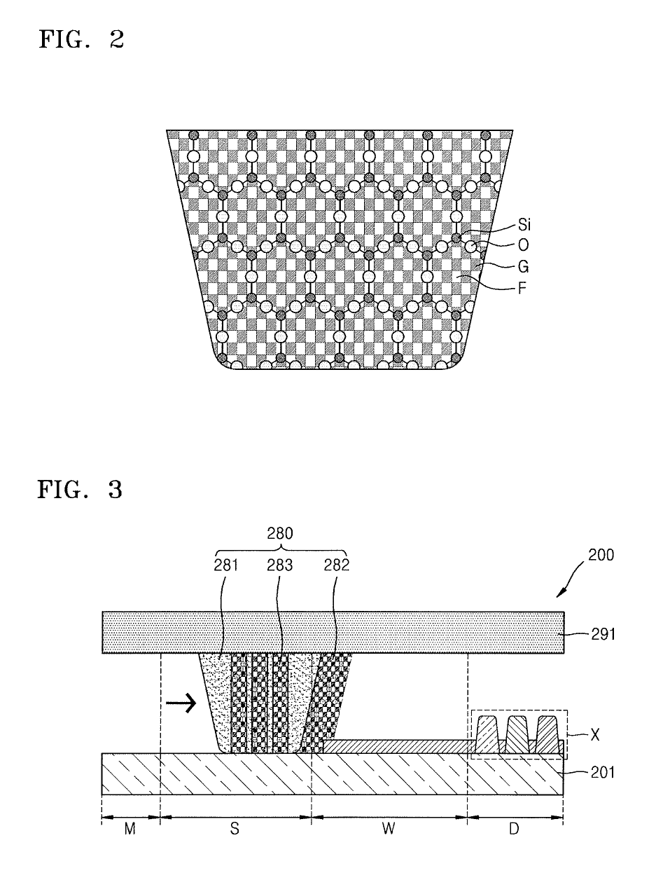

FIG. 2 illustrates an enlarged view of the sealing unit 180 of FIG. 1.

Referring to FIG. 2, the sealing unit 180 includes glass G formed of a glass frit and a binder including silicon (Si) as SiO₂. Also, the sealing unit 180 may further include a filler F so that the sealing unit 180 may have other various functions, as will be described in more detail below.

The glass frit in the glass G may have a glass transition temperature (Tg) lower than or equal to about 200° C. The glass frit may be formed in a paste form by adding a binder containing Si to powder including a low-temperature frit, and thus, the sealing unit 180 may be formed at a relatively low temperature of about 400° C. In this case, the Si contained in the binder may be crystallized at a temperature ranging from about 250° C. to about 300° C.

According to conventional technology, when a glass frit paste is sintered, a thermal treatment is used at a temperature of about 370° C. and above, and thus, a binder added to the glass frit paste may be decomposed. Further, use of a low glass transition temperature Tg of a low-temperature fit, which is lower than or equal to about 200° C., alone, i.e., without a binder, is close to a melting point, and thus, a sealing unit may not maintain its original form.

In contrast, the sealing unit 180 of the display apparatus 100 according to one or more embodiments includes a binder with Si, instead of a conventional binder that decomposes at a high temperature. Thus, as Si is not decomposed when the sealing unit 180 is sintered and remains as SiO₂, the resultant sealing unit 180 includes SiO₂ dispersed in the glass frit. In this case, the SiO₂ functions as a barrier together with the glass frit to prevent penetration of moisture, air, and other impurities from the outside into the display apparatus 100. Thus, the sealing unit 180, in which SiO₂ is. e.g., uniformly, dispersed in a main body of the glass fit, may have improved sealing characteristics. Also, as SiO₂ is not as highly brittle as the glass frit, the structural strength of the sealing unit 180 may be improved as well.

A cross-section of the sealing unit 180 is shown in FIG. 2. As discussed previously, the sealing unit 180 includes Si and oxygen (O) molecules dispersed in the glass G, i.e., in the glass frit.

The glass frit includes various materials. For example, the glass frit may include at least, e.g., vanadium (V) oxide and a bismuth (Bi) oxide. In particular, the glass frit may include vanadium oxide (V₂O₅) or bismuth oxide (Bi₂O₃). The V oxide or Bi oxide, e.g., V₂O₅ or Bi₂O₃, easily contact materials of the filler F, and thus, easily receive heat applied to the filler F. In another example, the glass frit may include, e.g., tellurium oxide (TeO₂), zinc oxide (ZnO), barium oxide (BaO), niobium oxide (Nb₂O₅), silicon oxide (SiO₂), aluminum oxide (Al₂O₃), zirconium oxide (ZrO₂), and phosphorus oxide (P₂O₅). As an example, with regard to the sealing unit 180, the glass frit may include V₂O₅ in an amount of about 10 to about 30 weight percent (wt %), TeO₂ in an amount of about 5 to about 25 wt %, ZnO in an amount of about 5 to about 25 wt %, and BaO in an amount of about 0 to about 10 wt %, based on a total weight of the sealing unit 180.

FIG. 3 illustrates a schematic cross-sectional view of an edge of a display apparatus 200 according to another exemplary embodiment.

Referring to FIG. 3, in the case of the display apparatus 200, the sealing unit 180 that is shown in FIG. 2, i.e., in which SiO₂ is dispersed in the glass frit, is not formed. Instead, a sealing unit 280 is mostly formed of a glass frit, and a portion of the sealing unit 280, which is adjacent to the display unit D, is formed of Si. That is, Si is not used as a binder, and the portion of the sealing unit 280 that is formed of Si overlaps the wiring unit W. For example, instead of uniformly dispersing SiO₂ in the entire sealing unit 280, only a portion of the sealing unit 280 contacting the wiring unit W includes Si, while remaining portions of the sealing unit 280 include glass frit without Si.

In detail, as illustrated in FIG. 3, the sealing unit 280 may include a first portion 281 formed of the glass frit without Si, a third portion 283 formed of SiO₂, and a second portion 282 formed of Si. However, the third portion 283 formed of SiO₂ may be omitted. The second portion 282 of the sealing unit 280 is formed of Si and overlaps the wiring unit W.

The first portion 281 is formed of glass frit without Si, and is formed in a paste form by using the same method as the method of forming a conventional glass frit paste. That is, a glass frit paste is patterned on a surface of a substrate 201 or an encapsulation substrate 291 in order to surround the display unit D, and then is sintered and dried. When the third portion 283 is formed, Si may be added and patterned in a center of the glass frit paste before the glass frit paste is sintered, and the patterned Si in the center of the glass frit paste is formed of SiO₂ and forms the third portion 283.

Si is further added and patterned to contact an inner surface of the glass frit paste, i.e., a portion of the glass frit paste contacting the wiring unit W, to define the second portion 282. The second portion 282 includes patterned Si, and may be arranged on the wiring unit W.

Laser beams are respectively irradiated on the glass frit paste with the Si patterns, e.g., in a gradually decreasing temperature from the outer portion toward the inner portion, to define the first and second portions 281 and 282. The first portion 281, which is formed of glass frit without Si and arranged outside the wiring unit W, is irradiated with a high-temperature laser beam, which nearly melts the glass frit, whereas the second portion 282, which is formed of Si and overlaps the wiring unit W, is irradiated with a low-temperature laser beam. That is, an outer portion of the glass frit, i.e., a portion facing the dead space M, includes no Si and is irradiated with the high-temperature laser beam, while an inner portion, i.e., a portion contacting the wiring unit W, includes Si and is irradiated with the low-temperature laser beam.

The glass frit paste is melted by the high-temperature laser beam, thereby becoming the first portion 281 formed of the glass frit without Si. Further, Si is crystallized in a central portion of the glass frit, i.e., between outer and inner portions, which is irradiated with the low-temperature laser beam, thereby defining the third portion 283 including SiO₂. Finally, as Si is not crystallized in the inner portion irradiated with the low-temperature laser beam, the inner portion becomes the second portion 282 formed of Si.

As shown in FIG. 3, a portion of the sealing unit 280 overlaps the wiring unit W in the display apparatus 200, and thus may be arranged to be more inside, i.e., closer to, the display unit D, e.g., as compared to a sealing unit completely spaced apart from a wiring unit in a conventional display apparatus. Accordingly, the dead space M may be reduced. Also, as the third portion 283 formed of SiO₂ and the second portion 282 formed of Si are respectively included in an inner portion of the sealing unit 280, which includes glass frit, sealing characteristics and structural strength of the sealing unit 280 may be improved.

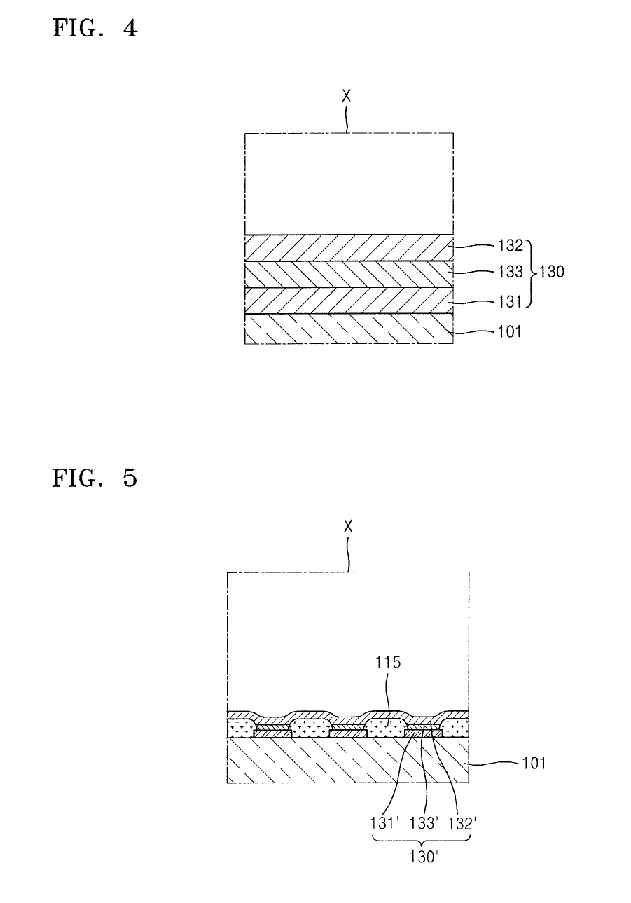

Hereinafter, the display unit D will be described with reference to FIG. 4. FIG. 4 illustrates an enlarged view of an area X of FIGS. 1 and 3.

Referring to FIGS. 2 and 4, the display unit D may include an organic light-emitting device 130. That is, in the present embodiment, a case where the display unit D includes an organic light-emitting device 130 will be described. However, embodiments are not limited thereto and the display unit D may include a LCD or other display unit devices.

Referring to FIG. 4, the organic light-emitting device 130 may be formed on the substrate 101, and may include a first electrode 131, an intermediate layer 133, and a second electrode 132. The first electrode 131 may function as an anode, and the second electrode 132 may function as a cathode. Polarities thereof may be reversed.

When the first electrode 131 functions as an anode, the first electrode 131 may include, e.g., indium tin oxide (ITO), indium zinc oxide (IZO), ZnO, or indium oxide (In₂O₃) having a high work function. Also, according to purpose and design conditions, the first electrode 131 may further include a reflective layer formed of, e.g., silver (Ag), magnesium (Mg), aluminum (Al), platinum (Pt), palladium (Pd), gold (Au), nickel (Ni), iridium (Ir), chromium (Cr), lithium (Li), ytterbium (Yb), calcium (Ca), or the like.

The intermediate layer 133 may include an emission layer emitting visible rays. Also, the intermediate layer 133 may selectively include at least one of a hole injection layer (HIL), a hole transport layer (HTL), an electron transport layer (ETL), and an electron injection layer (EIL).

When the second electrode 132 functions as a cathode, the second electrode 132 may include, e.g., Ag, Mg, Al, Pt, Pd, Au, Ni, ir, Cr, Li, or Ca. In addition, the second electrode 132 may include, e.g., ITO, IZO, ZnO, or In₂O₃ for light penetration.

When voltage is applied to the intermediate layer 133 via the first electrode 131 and the second electrode 132, the emission layer of the intermediate layer 133 emits a visible ray and an image may be displayed.

In the display apparatus 100, the sealing unit 180 is used to bond the substrate 101 and the encapsulation substrate 191 to each other. As the substrate 101 and the encapsulation substrate 191 are completely bonded to each other, and a space between the substrate 101 and the encapsulation substrate 191 is completely sealed, the display unit D is effectively protected.

Also, the sealing unit 180 includes glass frit and the filler F, so that a process of forming the sealing unit 180 is efficiently performed. In particular, the filler F may include at least Cr, copper (Cu), manganese (Mn) and an oxide having a spinel structure. For example, the filler F may include at least Cu(CrMn)₂O₄. As black Cr may be easily included in the filler, a laser-beam absorption rate of the sealing unit 180 including the filler is easily increased. Further, Cu enhances the spinel structure so that physical characteristics of the filler do not easily change at a high temperature. In particular, due to Cu, a color of the filler is maintained. Also, Mn restricts the filler from including an oxide having other crystalline structure than the spinel structure which is highly durable at a high temperature. Accordingly, the durability of the filler at a high temperature may be improved.

The filler F has a good absorption rate of a laser beam. The laser beam may have a wavelength ranging from about 700 nm to about 900 nm, e.g., about 800 nm. Thus, a laser beam irradiation process for forming the sealing unit 180 is quickly performed, and characteristics of the sealing unit 180 are improved. As a result, bonding characteristics of the substrate 101 and the encapsulation substrate 191 are improved.

Also, the glass frit may include, e.g., V₂O₅, TeO₂, ZnO, and BaO which effectively contact the filler including Cu(CrMn)₂O₄. Thus, the durability of the glass frit is improved due to the filler. In particular, when the sealing unit 180 is formed, heat of a laser beam is easily transmitted via the filler during the laser beam irradiation process, and thus, melting and hardening characteristics of the sealing unit 180 are improved.

There are various modified exemplary embodiments regarding the display unit D, and the modified exemplary embodiments will be described below.

FIG. 5 illustrates a schematic cross-sectional view according to a modified exemplary embodiment of FIG. 4.

Referring to FIG. 5, an organic light-emitting device 130′ may be formed on the substrate 101, and may include at least a first electrode 131′, an intermediate layer 133′, and a second electrode 132′.

In detail, the first electrode 131′ is formed on the substrate 101. A pixel-defining layer 115 is formed on the first electrode 131′ to expose a predetermined area of the first electrode 131′. The intermediate layer 133′ is formed on the first electrode 131′ to contact the first electrode 131′. The second electrode 132′ is formed on the intermediate layer 133′.

The first electrode 131′ functions as an anode, and the second electrode 132′ functions as a cathode. Polarities of the first electrode 131′ and the second electrode 132′ may be reversed. The intermediate layer 133′ may include an emission layer emitting visible rays. Also, the intermediate layer 133′ may selectively include at least one of a hole injection layer, a hole transport layer, an electron transport layer, and an electron injection layer.

In this case, the intermediate layer 133′ may emit lights of a variety of colors, for example, red, green, and blue. As another example, the intermediate layer 133′ may emit light of one color. For example, when the intermediate layer 133′ emits white light, a color conversion component such as a color filter, other than the intermediate layer 133′, may also be included. Materials for forming the first electrode 131′ and the second electrode 132′ are the same as presented above, and thus, detailed descriptions thereof will be omitted.

FIG. 6 illustrates a schematic cross-sectional view of another modified exemplary embodiment of FIG. 4.

Referring to FIG. 6, the display unit D may include an organic light-emitting device 130″ and a TFT, and the organic light-emitting device 130″ includes at least a first electrode 131″, an intermediate layer 133″, and a second electrode 132″. The TFT may include an active layer 141, a gate electrode 142, a source electrode 143, and a drain electrode 144. Detailed descriptions thereof are provided below.

The buffer layer 121 is formed on the substrate 101. The active layer 141 having a predetermined pattern is formed on the buffer layer 121. The active layer 141 may include an inorganic semiconductor including, for example, Si, an organic semiconductor, or an oxide semiconductor, and may include a source area, a drain area, and a channel area.

A gate insulating layer 122 is formed on the active layer 141, and the gate electrode 142 is formed in a predetermined area of the gate insulating layer 122. The gate insulating layer 122 insulates the active layer 141 and the gate electrode 142 and may include an organic material or an inorganic material such as SiNₓ and SiO₂.

The gate electrode 142 may contain Au, Ag, Cu, Ni, Pt, Pd, Al, and Mo and alloys such as Al:Nd, Mo:W, but is not limited thereto. The gate electrode 142 may be formed of various materials in consideration of adhesion to an adjacent layer, flatness, an electric resistance, workability, etc.

An interlayer insulating layer 123 is formed on the gate electrode 142. The interlayer insulating layer 123 and the gate insulating layer 122 expose the source area and the drain area of the active layer 141, and the source electrode 143 and the drain electrode 144 are formed to contact the exposed source area and drain area of the active layer 141. The source electrode 143 and the drain electrode 144 may include various conductive materials and may have a single-layer structure or a multilayer structure.

A passivation layer 124 is formed on the TFT. In detail, the passivation layer 124 is formed on the source electrode 143 and the drain electrode 144.

The passivation layer 124 exposes a predetermined area of the drain electrode 144 instead of covering an entire area of the drain electrode 144, and the first electrode 131″ is connected to the drain electrode 144 having the exposed predetermined area.

A pixel-defining layer 125 includes an insulating material and is formed of on the first electrode 131″. The pixel-defining layer 125 exposes a predetermined area of the first electrode 131″. The intermediate layer 133″ contacts the first electrode 131″, and the second electrode 132″ is connected to the intermediate layer 133″.

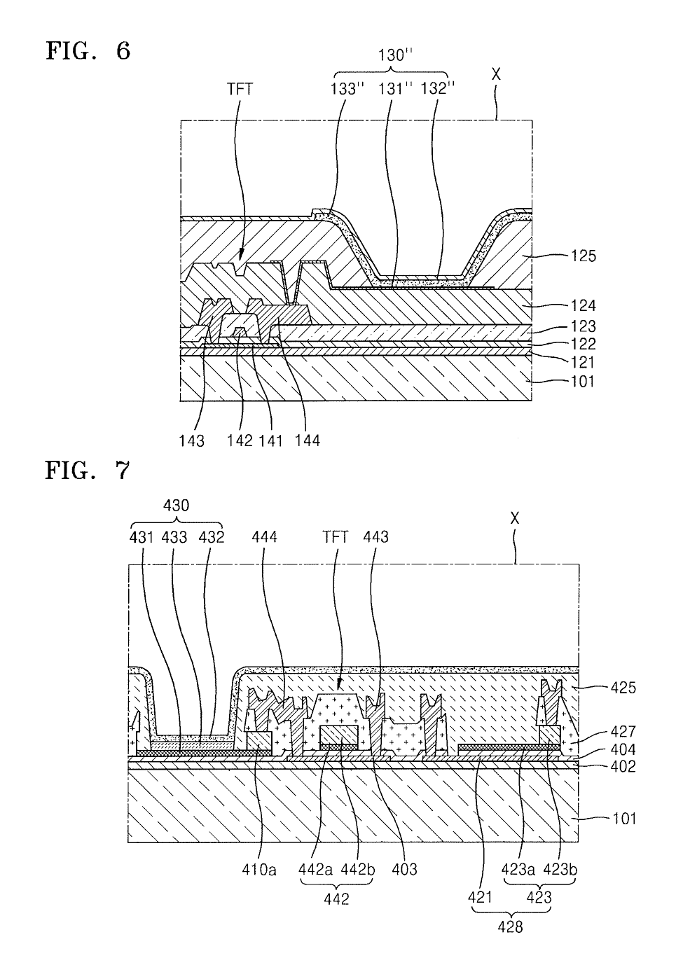

FIG. 7 illustrates a schematic cross-sectional view according to a modified exemplary embodiment of FIG. 6.

Referring to FIG. 7, the display unit D may include an organic light-emitting display unit device 430 and a TFT. The organic light-emitting device 430 includes a first electrode 431, an intermediate layer 433, and a second electrode 432. The TFT includes an active layer 403, a gate electrode 442, a source electrode 443, and a drain electrode 444. Detailed descriptions of the active layer 403, the gate electrode 442, the source electrode 443, and the drain electrode 444 will be provided below.

A buffer layer 402 is formed on the substrate 101. The active layer 403 having a predetermined size is formed on the buffer layer 402. Also, a first capacitor electrode 421 is formed on the buffer layer 402. The first capacitor electrode 421 and the active layer 403 include the same material. A gate insulating layer 404 is formed on the buffer layer 402 in order to cover the active layer 403 and the first capacitor electrode 421.

The gate electrode 442, the first electrode 431, and the second capacitor electrode 423 are formed on the gate insulating layer 404. The gate electrode 442 includes a first conductive layer 442a and a second conductive layer 442b. The first electrode 431 may include the same material as the first conductive layer 442a. The conductive portion 410a is arranged on a predetermined area of the first electrode 431 and includes the same material as the second conductive layer 442b.

The second capacitor electrode 423 includes a first layer 423a and a second layer 423b. The first layer 423a includes the same material as the first conductive layer 442a, and the second layer 423b includes the same material as the second conductive layer 442b. The second layer 423b is formed on the first layer 423a and is smaller than the first layer 423a. The second capacitor electrode 423 overlaps the first capacitor electrode 421 and is smaller than the first capacitor electrode 421.

An interlayer insulating layer 427 is formed on the first electrode 431, the gate electrode 442, and the second capacitor electrode 423. The source electrode 443 and the drain electrode 444 are also formed on the active layer 403. The source electrode 443 and the drain electrode 444 are connected to the active layer 403.

In addition, any one of the source electrode 443 and the drain electrode 444 is electrically connected to the first electrode 431, and according to FIG. 7, the drain electrode 444 is electrically connected to the first electrode 431. In detail, the drain electrode 444 contacts the conductive portion 410a.

A pixel-defining layer 425 is formed on the interlayer insulating layer 427 in order to cover the source electrode 443, the drain electrode 444, and a capacitor 428. The pixel-defining layer 425 does not cover a predetermined portion of an upper surface of the first electrode 431, and an intermediate layer 433 is formed to contact an exposed portion of the upper surface of the first electrode 431. The second electrode 432 is formed on the intermediate layer 433.

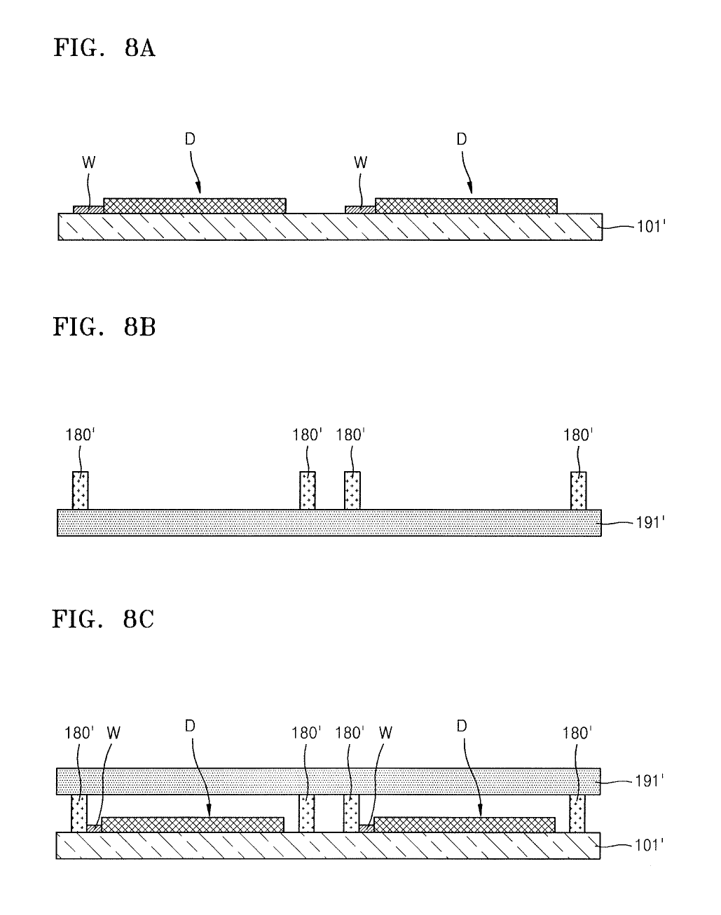

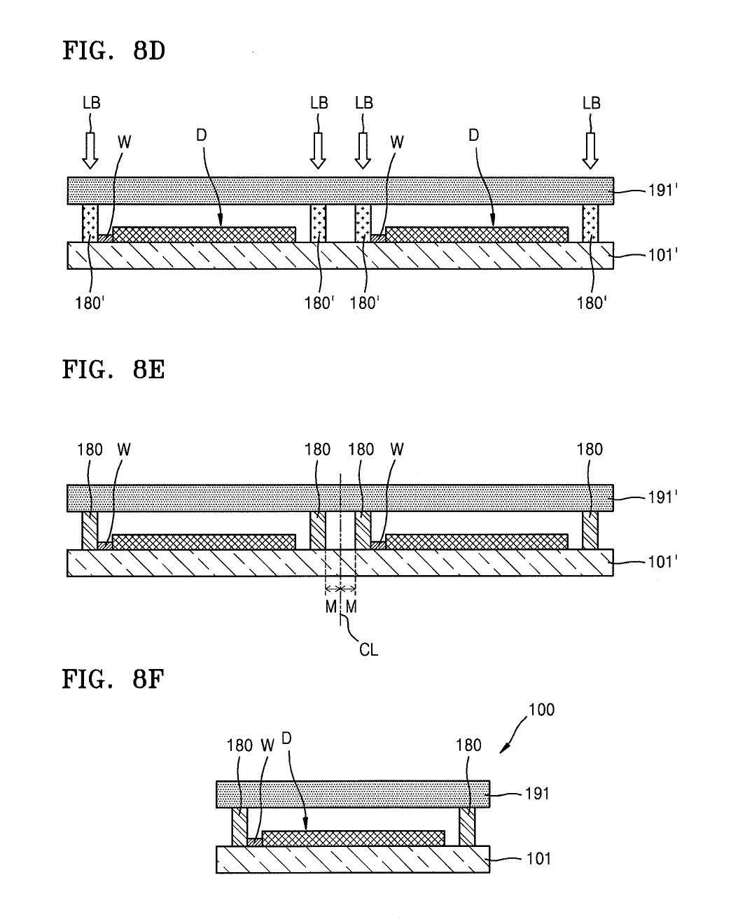

FIGS. 8A to 8F illustrate stages in a method of manufacturing a display apparatus, according to an exemplary embodiment. For example, FIGS. 8A to 8F show a method of manufacturing the display apparatus 100 of FIG. 1.

Referring to FIG. 8A, a mother substrate 101′ is prepared. The mother substrate 101′ may include, e.g., glass, plastic, or the like. For example, the mother substrate 101′ may include a transparent material.

One or more displays D may be formed on the mother substrate 101′. For example, referring to FIG. 8A, two displays D are formed. However, the number of the displays D is not limited. The wiring unit W is adjacent to the displays D and is extended toward an edge of the substrate 101.

Referring to FIG. 8B, a preliminary sealing unit 180′ is formed on a mother encapsulation substrate 191′. The preliminary sealing unit 180′ may be formed to surround each display unit D of the mother substrate 101′ at a location overlapping the wiring unit W.

The preliminary sealing unit 180′ is formed on the mother encapsulation substrate 191′ in a paste form. In detail, the preliminary sealing unit 180′ is in the form of a paste including a glass frit and a binder containing Si. The glass frit and the binder containing Si are the same as explained above, and thus, detailed descriptions thereof will be omitted. Also, although not illustrated, as another example, it is possible to form the preliminary sealing unit 180′ on a surface of the mother substrate 101′ to surround the displays D and at least overlaps the wiring unit W.

An example in which the preliminary sealing unit 180′ in a paste form is manufactured is described in detail as follows. First, a powder including a glass frit is prepared. A paste is prepared by adding a binder including Si and other solutions to the powder. Then, the paste is placed on the mother encapsulation substrate 191′ as desired in order to form the preliminary sealing unit 180′. In this case, a screen printing method is used to form the preliminary sealing unit 180′ on the mother encapsulation substrate 191′ as desired. The preliminary sealing unit 180′ in the paste form is then sintered and dried.

Referring to FIG. 8C, the mother encapsulation substrate 191′ faces the mother substrate 101′. In this case, the preliminary sealing unit 180′ is arranged between the mother substrate 101′ and the mother encapsulation substrate 191′, such that the preliminary sealing unit 180′ surrounds the displays D and overlaps at least the wiring unit W.

Referring to FIG. 8D, the mother encapsulation substrate 191′ is irradiated with a laser beam LB. In detail, the laser beam LB is irradiated toward the preliminary sealing unit 180′. When the laser beam LB is emitted, the preliminary sealing unit 180′ is sintered and then hardened, and thus, the mother substrate 101′ and the mother encapsulation substrate 191′ are bonded to each other. Si contained in the preliminary sealing unit 180′ is crystallized and SiO₂ is formed. The laser beam LB needs to have a temperature lower than or equal to 400° C. in order to prevent damage of the wiring unit W.

As shown in FIG. 8E, the preliminary sealing unit 180′ changes to the sealing unit 180 which bonds the mother substrate 101′ and the mother encapsulation substrate 191′ by emitting the laser beam LB. Next, the mother substrate 101′ and the mother encapsulation substrate 191′ are cut along a cutting line CL. As a result, as shown in FIG. 8F, the display apparatus 100 is manufactured.

By way of summation and review, glass frit is usually used as a sealing unit. However, a circuit unit and an emission area may be damaged due to heat generated by a laser beam while the frit is melted and sintered. Further, when the frit is arranged in an outermost area of the substrate to prevent this damage, a dead space may increase.

In contrast, according to example embodiments, a display apparatus 100 may include a sealing unit having SiO₂ dispersed in the glass frit, and thus, the sealing characteristics and strength of the sealing unit are improved. In addition, as the sealing unit is arranged to overlap the wiring unit, the dead space between the mother substrate and the mother encapsulation substrate may be reduced.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A display apparatus, comprising:
a substrate;
an encapsulation substrate that faces the substrate;
a display unit on the substrate, the display unit including a display device to display an image; and
a sealing unit bonding the substrate and the encapsulation substrate to each other, the sealing unit being separated from the display unit and including silicon oxide and glass frit.

2. The display apparatus of claim 1, wherein a portion of the sealing unit adjacent to the display unit includes silicon.

3. The display apparatus as claimed in claim 1, wherein a glass transition temperature (Tg) of the glass frit is lower than or equal to about 200° C.

4. The display apparatus as claimed in claim 3, wherein the glass frit contains at least vanadium oxide or bismuth oxide.

5. The display apparatus as claimed in claim 4, wherein the vanadium oxide contains V₂O₅ and the bismuth oxide contains Bi₂O₃.

6. The display apparatus as claimed in claim 3, wherein the glass frit contains at least one of TeO₂, ZnO, and BaO.

7. The display apparatus as claimed in claim 1, further comprising a wiring unit connected to the display unit, the wiring unit including a plurality of wires extending toward an edge of the substrate.

8. The display apparatus as claimed in claim 7, wherein the sealing unit surrounds the display unit and overlaps at least the wiring unit.

9. The display apparatus as claimed in claim 1, wherein a gap between the substrate and the encapsulation substrate is sealed by the sealing unit.

10. The display apparatus as claimed in claim 1, wherein the display unit includes an organic light-emitting display device, the organic light-emitting display device having a first electrode, a second electrode, and an intermediate layer between the first electrode and the second electrode and including an emission layer.

11. The display apparatus as claimed in claim 10, further comprising a thin-film transistor (TFT) electrically connected to the first electrode, the TFT including an active layer, a gate electrode, a source electrode, and a drain electrode.

12. A method of manufacturing a display apparatus, the method comprising:
preparing a substrate and an encapsulation substrate that faces the substrate;
forming a display unit between the substrate and the encapsulation substrate, the display unit including a display device to display an image; and
bonding the substrate and the encapsulation substrate via a sealing unit, the sealing unit being formed by sintering glass frit with silicon oxide.

13. The method as claimed in claim 12, wherein the bonding includes:
forming a preliminary sealing unit by preparing a paste including glass frit and silicon oxide on a surface of the substrate or the encapsulation substrate;
sintering and drying the preliminary sealing unit; and
melting and hardening the preliminary sealing unit by emitting a laser beam, after the preliminary sealing unit is sintered and dried, such that the preliminary sealing unit becomes the sealing unit.

14. The method as claimed in claim 13, wherein preparing the paste includes preparing a powder containing the glass frit and adding the silicon oxide and a solution to the powder.

15. The method as claimed in claim 14, wherein the silicon oxide is formed of silicon crystallized at a temperature ranging from about 250 to about 300° C.

16. The method as claimed in claim 13, wherein forming the preliminary sealing unit includes forming the paste by using a screen printing method.

17. The method as claimed in claim 12, wherein preparing the substrate and encapsulation substrate includes:
preparing a mother substrate greater than the substrate and a mother encapsulation substrate greater than the encapsulation substrate; and
performing a cutting process on the mother substrate and the encapsulation substrate after the sealing unit is formed.

18. The method as claimed in claim 17, wherein the display unit includes a plurality of display units, and the cutting process is performed to separate the plurality of display units from each other.

19. The method as claimed in claim 18, wherein the sealing unit surrounds each of the plurality of display units.

20. The method as claimed in claim 13, wherein a temperature of the laser beam is lower than or equal to about 400° C.
